(19) United States
(12) Patent Application Publication
(10) Pub. No.: US 2002/0191384 A1
(43) Pub. Date: Dec. 19, 2002

(54) Metal housing grounding mechanism

(76) Inventor: Shin-Fu Wei, Taipei (TW)

Correspondence Address: JACOBSON HOLMAN PLLC, 400 SEVENTH STREET N.W., SUITE 600, WASHINGTON, DC, 20004, US

(21) Appl. No.: 09/883,227

(22) Filed: Jun. 19, 2001

(51) Int. Cl. H05K 7/14

(52) U.S. Cl. 361/799

(57) ABSTRACT

A metal housing grounding mechanism comprises a housing, a circuit board inside the housing; a connector is on one side of the circuit board. Two metal boards are on top and bottom of the connector; one of the metal boards is connected to ground. A spring tongue is on both ends of the two metal boards. The spring tongues of one metal board and the spring tongues of the other metal board brace together. Therefore the two metal boards are connected and conducted together for better shield against electromagnetic wave and static electricity.

### BACKGROUND OF THE INVENTION

I. Field of the Invention

This invention relates generally to a metal housing grounding mechanism and, more specifically, to a metal housing grounding mechanism that improves the anti-electromagnetic interference and anti-static electricity effect.

II. Description of the Prior Art

Heretofore, it is known that most of the memory cards for digital cameras and PDA's (Personal Data Assistant) consists a housing with a circuitry board inside, a connector is on one end of the circuitry board, metal boards are on top and bottom of the connector.

Memory cards are easily interfered by electromagnetic wave that can destroy the stored data or make errors while transferring data. When moving the memory card, the static electricity can be conducted through the metal boards on top and bottom of the connector to the circuitry board and break, damage the memory chips.

Most of the known metal boards of memory cards do not have grounding structure, the anti-electromagnetic interference effect is not so good as to prevent memory chips from damage, therefore it is better to have the metal boards connecting to ground to eliminate electromagnetic wave and static electricity.

Most of the known metal boards of memory cards have only one metal board connects to circuitry board, the other metal board is in simpler format and is not connected to circuitry board, therefore the anti-electromagnetic interference and anti-static electricity effect is not so good.

Some of the known metal boards of memory cards bend downward on two sides, the scheme makes the metal boards fix inside the housing frame of the memory cards, the metal boards connect to the housing by means of the bending portion. However when the metal boards are fixed to the housing, the bending portion might not contact completely or even not contact to the housing, therefore such scheme can not achieve the anti-electromagnetic interference and anti-static electricity effect.

### SUMMARY OF THE INVENTION

It is therefore a primary object of the invention to provide a metal housing grounding mechanism to achieve the anti-electromagnetic interference and anti-static electricity effect for the memory cards of digital cameras and PDA's.

In order to achieve the objective set forth, a metal housing grounding mechanism in accordance with the present invention comprises a housing, a circuit board inside the housing; a connector is on one side of the circuit board. Two metal boards are on top and bottom of the connector respectively; one of the metal boards is connected to ground. A spring tongue is installed on both ends of the two metal boards. The spring tongues of one metal board and the spring tongues of the other metal board brace together so that the two metal boards are connected and conducted together for better shield against electromagnetic wave and static electricity.

### BRIEF DESCRIPTION OF THE DRAWINGS

The accomplishment of the above-mentioned object of the present invention will become apparent from the following description and its accompanying drawings which disclose illustrative an embodiment of the present invention, and are as follows:

FIG. 1 is a perspective view of the present invention;

FIG. 2 is an assembly view of a further embodiment of the present invention;

FIG. 3 is another assembly view of a further embodiment of the present invention.

### DESCRIPTION OF THE PREFERRED EMBODIMENT

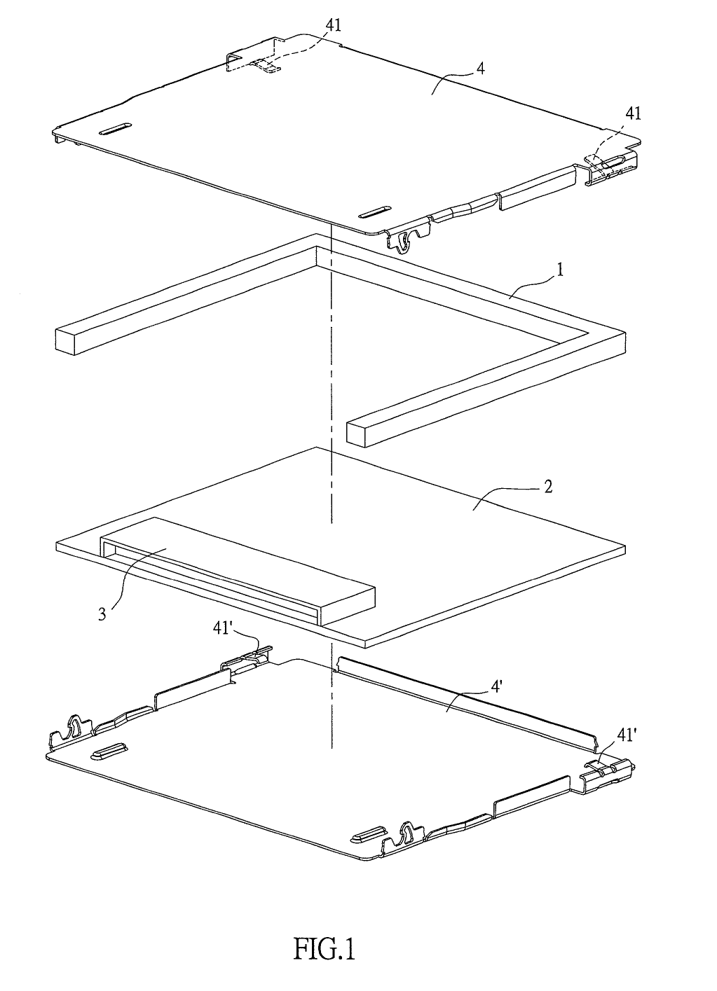

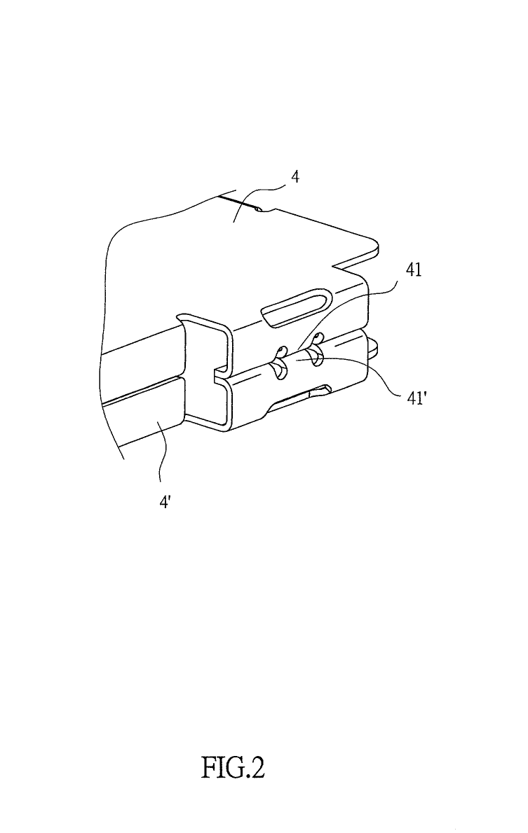

Referring to FIG. 1 and FIG. 2, the present invention is composed of a housing 1, a circuit board 2 inside of the housing 1, a connector 3 is arranged on one side of the circuit board 2. Two metal board 4 and 4′ are installed on top and bottom of the connector 3 respectively while one of the metal board 4 is connected to ground.

A spring tongue 41 is disposed on both ends of the metal board 4 and 4′. The spring tongue 41 of the metal board 4 and the spring tongue 41 of the metal board 4′ brace together so that the two metal board 4 and 4′ are connected together.

Based on above description, the two metal board 4 and 4′ are connected to each other through the spring tongue 41 on both ends of the metal board 4 and 4′. One of the metal board 4 or 4′ connects to the ground of the circuitry board 2. Thus the two metal board 4 and 4′ are both ground to have better shield against electromagnetic wave and static electricity.

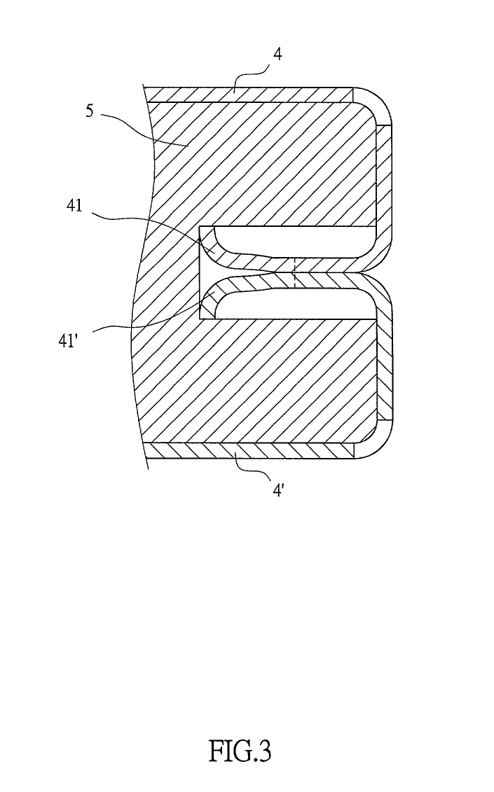

The spring tongue 41 of the metal board 4 and 4′ have elasticity. Therefore when being molding, two spring tongue 41 brace together to prevent two metal board 4 and 4′ from separating. A plastic plate 5 can further fix the two spring tongue 41 together, as shown in FIG. 3, to make sure that the metal board 4 and 4′ from bad contact situation.

While a preferred embodiment of the invention has been shown and described in detail, it will be readily understood and appreciated that numerous omissions, changes and additions may be made without departing from the spirit and scope of the invention.

What is claimed is:

1. A metal housing grounding mechanism comprising:
a housing;
a circuit board inside said housing,
a connector installed on one side of said circuit board;
two metal boards located on top and bottom of said connector respectively while one of said two metal boards connected to ground;
a spring tongue located on both ends of said metal board,
wherein said spring tongue of one said metal board and said spring tongue of the other said metal board brace together so as to make the two said metal board connect and conduct together.
